(19) United States
(12) Patent Application Publication
(10) Pub. No.: US 2006/0075972 A1
(43) Pub. Date: Apr. 13, 2006

(54) Substrate processing apparatus and substrate processing method

(75) Inventors: Seiyo Nakashima, Tokyo (JP); Michiko Nishiwaki, Tokyo (JP); Yukinori Aburatani, Tokyo (JP); Satoshi Okada, Tokyo (JP); Eisuke Nishitani, Tokyo (JP); Kazuhiro Nakagomi, Tokyo (JP); Kazuhito Ikeda, Tokyo (JP); Kazuhiro Shimeno, Tokyo (JP); Gakuji Ohta, Tokyo (JP); Katsuhisa Kasanami, Tokyo (JP)

Correspondence Address: HOGAN & HARTSON L.L.P., 500 S. GRAND AVENUE, SUITE 1900, LOS ANGELES, CA, 90071-2611, US

(73) Assignee: Hitachi Kokusai Electric Inc.

(21) Appl. No.: 11/258,670

(22) Filed: Oct. 25, 2005

Related U.S. Application Data
(63) Continuation of application No. 09/816,643, filed on Mar. 23, 2001, now abandoned.

(30) Foreign Application Priority Data
Mar. 24, 2000 (JP) 2000-84590

(51) Int. Cl. C23C 16/00

(52) U.S. Cl. 118/729; 118/719; 118/730; 118/725

(57) ABSTRACT

A substrate processing apparatus comprises a processing chamber; a susceptor on which a substrate to be processed is to be placed; and a heating unit disposed below the susceptor for heating the substrate to be processed placed on the susceptor. The susceptor and the heating unit are accommodated in the processing chamber, and in a state in which the susceptor and the heating unit are relatively rotated, the substrate to be processed is processed. At least the susceptor is lifted and lowered in the processing chamber, and a substrate to be processed lifting and lowering apparatus for lifting and lowering the substrate to be processed with respect to at least a portion of the susceptor is disposed in the processing chamber.

### BACKGROUND OF THE INVENTION

1. Field of the Invention

The present invention relates to a substrate processing apparatus and a substrate processing method, and more particularly, to a substrate processing technique for subjecting a substrate to be processed to a desired processing utilizing thermochemical reaction, and still more particularly, to a transfer technique of a substrate to be processed using a susceptor. The present invention is effectively utilized for a substrate processing technique for forming an oxide film or a metal film on a semiconductor wafer (wafer, hereinafter) in a producing step of a semiconductor device.

2. Description of the Related Art

In the producing method of the semiconductor device, to form the oxide film or metal film on the wafer, a single wafer-fed (single wafer by single wafer type) cold wall type CVD apparatus (single wafer-fed CVD apparatus, hereinafter) is used in some cases. A conventional single wafer-fed CVD apparatus of this type comprises a processing chamber for accommodating wafers as substrates to be processed, a susceptor for holding the wafers one by one in the processing chamber, a heating unit for heating the wafer held by the susceptor, a gas head for supplying processing gas to the wafer held by the susceptor, and an exhaust port for evacuating the processing chamber.

In the single wafer-fed CVD apparatus, in order to control film thickness and film quality of a CVD film to be formed on the wafer uniformly over the entire film, Japanese Patent No. 2966025 and Japanese Patent Application Laid-open No. 9-7955 for example propose a single wafer-fed CVD apparatus for controlling a temperature distribution of a wafer uniformly over the entire wafer, and for bringing processing gas into contact with the wafer uniformly over the entire wafer by rotating a susceptor holding the wafer.

In the single wafer-fed CVD apparatus proposed in the above publications, however, since the wafer can not be floated up from the susceptor, it is necessary to absorb and hold an upper surface of the wafer by a vacuum absorption and holding apparatus or a static absorption and holding apparatus to transfer the wafer into and, from the susceptor from above, and there is a problem that this complicates a structure of a wafer transfer apparatus for transferring the wafer to and from the susceptor, and an application range of the CVD apparatus is limited due to properties of the vacuum absorption and holding apparatus or the static absorption and holding apparatus.

### SUMMARY OF THE INVENTION

It is an object of the present invention to provide a substrate processing technique capable of rotating a susceptor and capable of mechanically transferring a substrate to be processed to and from the susceptor.

According to a first aspect of the present invention, there is provided a substrate processing apparatus, comprising:

a processing chamber;

a susceptor on which a substrate to be processed is to be placed; and

a heating unit disposed below the susceptor for heating the substrate to be processed placed on the susceptor, wherein

the susceptor and the heating unit are accommodated in the processing chamber,

in a state in which the susceptor and the heating unit are relatively rotated, the substrate to be processed is processed,

at least the susceptor is lifted and lowered in the processing chamber, and

a substrate to be processed lifting and lowering apparatus for lifting and lowering the substrate to be processed with respect to at least a portion of the susceptor is disposed in the processing chamber.

According to the above-described substrate processing apparatus, when the substrate to be processed is transferred to and from the susceptor, a space (vacant space) can be formed below the substrate to be processed by lifting and lowering the substrate to be processed by the substrate to be processed lifting and lowering apparatus. Therefore, a tweezer of a mechanical type substrate transfer apparatus can be inserted into the space. That is, by inserting the tweezer into the space below the substrate to be processed, the substrate to be processed can be mechanically supported by the tweezer from below and thus, the substrate to be processed can be transferred by the mechanical type substrate transfer apparatus. That is, it is unnecessary to use a vacuum absorption and holding apparatus or a static absorption and holding apparatus having a complicated structure for transferring the substrate to be processed.

According to a second aspect of the present invention, there is provided a substrate processing apparatus, comprising
a susceptor disposed in a processing chamber and on which a substrate to be processed is to be placed, and
a heating unit disposed below the susceptor in the processing chamber for heating the substrate to be processed placed on the susceptor, wherein
an upper surface of a peripheral portion of the susceptor and an upper surface of the substrate to be processed placed on the susceptor are flush with each other.

According to a third aspect of the present invention, there is provided a substrate processing method using a substrate processing apparatus, comprising:

a processing chamber;

a susceptor on which a substrate to be processed is to be placed; and

a heating unit disposed below the susceptor for heating the substrate to be processed placed on the susceptor, wherein

the susceptor and the heating unit are accommodated in the processing chamber,

in a state in which the susceptor and the heating unit are relatively rotated, the substrate to be processed is processed,

at least the susceptor is lifted and lowered in the processing chamber, and

a substrate to be processed lifting and lowering apparatus for lifting and lowering the substrate to be processed with respect to at least a portion of the susceptor is disposed in the processing chamber, comprising the steps of:

transferring the substrate to be processed from the susceptor to the substrate to be processed lifting and lowering apparatus when the susceptor is lowered, and

processing the substrate to be processed when the susceptor is lifted in a state in which the substrate to be processed is placed by the susceptor.

According to the substrate processing method according to the third aspect of the present invention, when the substrate to be processed is processed, the susceptor is rotated to rotate the substrate to be processed, so that a temperature distribution on the substrate to be processed heated by the heating unit becomes uniform over the entire substrate to be processed, and the substrate to be processed is brought into contact with the atmosphere in the processing chamber uniformly over the entire substrate to be processed. As a result, the substrate to be processed is processed uniformly over the entire substrate to be processed.

### BRIEF DESCRIPTION OF THE DRAWINGS

The above and further objects, features and advantages of the present invention will become more apparent from the following detailed description taken in conjunction with the accompanying drawings, wherein:

FIG. 1 is a front sectional view showing a wafer transferring in-out step using a single wafer-fed CVD apparatus according to a first aspect of the present invention;

FIG. 2 is a perspective view showing a principal part of the single wafer-fed CVD apparatus shown in FIG. 1;

FIG. 3 is a front sectional view showing a processing step using the single wafer-fed CVD apparatus shown in FIG. 1;

FIG. 4 is a perspective view showing a principal part of the single wafer-fed CVD apparatus shown in FIG. 3;

FIG. 5 is a front sectional view showing a wafer transferring in-out step using a single wafer-fed CVD apparatus according to a second aspect of the present invention,

FIG. 6 is a perspective view showing a principal part of the single wafer-fed CVD apparatus shown in FIG. 5;

FIG. 7 is a front view, partly in section, showing a processing step using the single wafer-fed CVD apparatus shown in FIG. 5;

FIG. 8 is a perspective view showing a principal part of the single wafer-fed CVD apparatus shown in FIG. 7;

FIG. 9A, 9B are front sectional views for explaining operation of a wafer lifting and lowering apparatus, FIG. 9A shows when a wafer is floated up and FIG. 9B shows when the wafer is placed;

FIG. 10 is a front view, partly in section, showing one embodiment of a rotation driving apparatus for fixing a support shaft and for rotating a rotating shaft;

FIG. 11 is a front sectional view showing a wafer transferring in-put step using a single wafer-fed CVD apparatus according to a third aspect of the present invention;

FIG. 12 is a perspective view showing a principal part of the single wafer-fed CVD apparatus shown in FIG. 11;

FIG. 13 is a front view, partly in section, showing a processing step using the single wafer-fed CVD apparatus shown in FIG. 11;

FIG. 14 is a perspective view showing a principal part of the single wafer-fed CVD apparatus shown in FIG. 13;

FIG. 15A-15C are front sectional views for explaining heater operation, FIG. 15A shows heating operation during processing, FIG. 15B shows heating operation during carrying in and out, and FIG. 15C shows heating operation during carrying in and out in a comparison example;

FIG. 16 is a front sectional view showing a wafer transferring in-out step using a single wafer-fed CVD apparatus according to a fourth aspect of the present invention; and

FIG. 17 is a front view, partly in section, showing a processing step using the single wafer-fed CVD apparatus shown in FIG. 16.

### DESCRIPTION OF THE PREFERRED EMBODIMENTS

A substrate processing apparatus according to are embodiment of the present invention will be explained with reference to the drawings below.

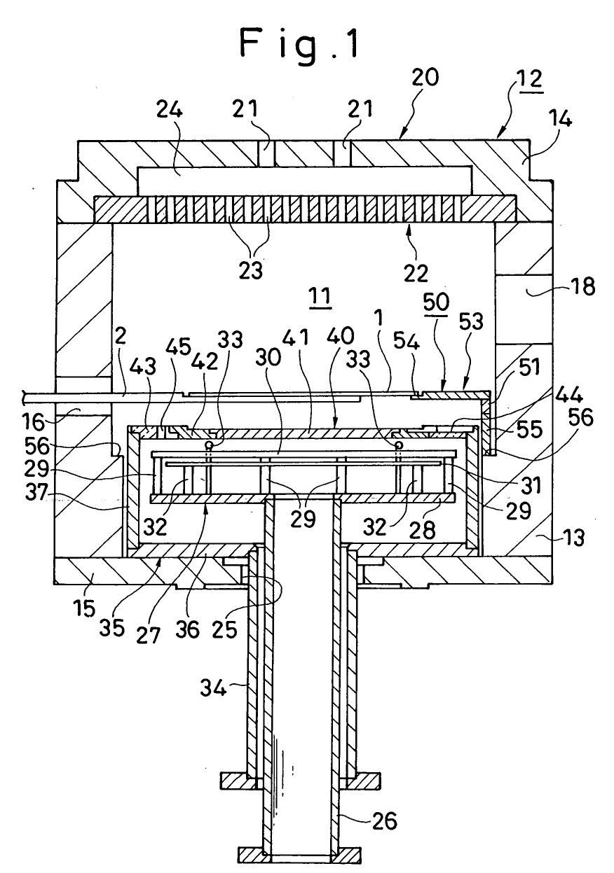

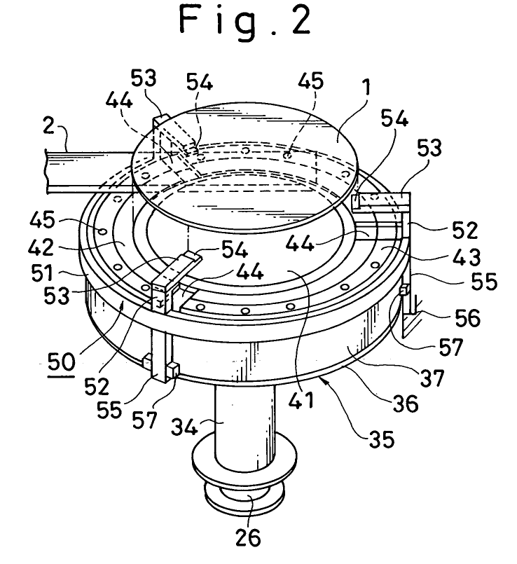

As shown in FIGS. 1 and 2, the substrate processing apparatus of the invention is formed as a single wafer-fed CVD apparatus (single wafer-fed cold wall type CVD apparatus). The substrate processing apparatus comprises a chamber 12 in which a processing chamber 11 for processing wafers 1 (semiconductor wafers) 1 as substrates to be processed is formed. The chamber 12 is formed into a cylindrical shape comprising a lower cap 13, an upper cap 14 and a bottom cap 15 combined together. Both upper and lower end surfaces of the chamber 12 are closed.

A wafer carry in-out port 16 is transversely formed in a central portion of a cylindrical wall of the lower cap 13 of the chamber 12 in the horizontal direction. The wafer carry in-out port 16 is opened and closed by a gate valve 17. A mechanical wafer transfer transfers the wafer 1 into and from the processing chamber 11 through the wafer carry in-out port 16. That is, as shown in FIG. 1, the wafer 1 is mechanically supported from below by a tweezer 2 of a mechanical wafer transfer apparatus and in this state, the wafer 1 is transferred into and from the processing chamber 11 through the wafer carry in-out port 16.

An exhaust port 18 is formed in a wall surface of the lower cap 13 opposed to the wafer carry in-out port 16 at a position slightly higher than the wafer carry in-out port 16. A vacuum exhaust apparatus (not shown) comprising a vacuum pump or the like is fluidly connected to the exhaust port 18, and the exhaust port 18 is in communication with the processing chamber 11. The exhaust port 18 is evacuated to a predetermined degree of vacuum by the vacuum exhaust apparatus.

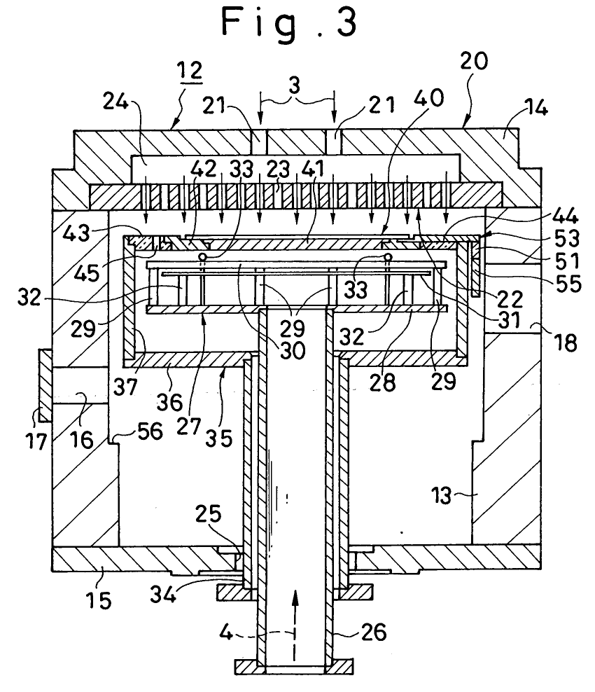

A gas head 20 for supplying processing gas is integrally incorporated into the upper cap 14 of the chamber 12. That is, a plurality of gas introducing ports 21 are formed in a ceiling wall of the upper cap 14. Gas supply apparatus (not shown) for introducing processing gas 3 (see FIG. 3) such as raw gas or purge gas is connected to the gas introducing ports 21 through gas introducing tubes (not shown). A disc-like gas-blowout plate (plate, hereinafter) 22 is horizontally fitted and fixed between mating surfaces of the upper cap 14 and the lower cap 13 at a distance from the gas introducing ports 21. A plurality of gas-blowout ports (blowout ports, hereinafter) 23 are uniformly formed in the plate 22 over its entire surface so that the upper and lower portions can be brought into communication with each other. A gas reservoir 24 is formed by an inner space defined by an inner surface of the upper cap 14 and an upper surface of the plate 22. The gas reservoir 24 disperses the processing gas introduced into the gas introducing ports 21 entirely uniformly and blows out the processing gas uniformly like shower.

A insertion hole 25 is formed in the center of the bottom cap 15 of the chamber 12, and a cylindrical support shaft 26 is inserted into the processing chamber 11 from below on a center line of the insertion hole 25. The support shaft 26 is lifted and lowered by a lifting and lowering driving apparatus (not shown) using an air cylinder apparatus or the like. A nitrogen gas supply apparatus (not shown) for supplying nitrogen gas (see FIG. 3) as inert gas is connected to a cylindrical hollow portion of the support shaft 264

A heating unit 27 is concentrically disposed on an upper end of the support shaft 26 and horizontally fixed thereto, and the heating unit 27 is lifted and lowered by the support shaft 26. That to, the heating unit 27 is provided with a doughnut-like flat-plate shaped support plate 28, and an inner peripheral portion of the support plate 28 is fixed to an upper end opening of the support shaft 26. A plurality of electrodes 29 serving also as columns vertically stand on an upper surface of the support plate 28 at a plurality of inner peripheral locations and outer peripheral locations of the support plate 28. A heater 30 bridges over and fixed between upper ends of the electrodes 29. The heater 30 entirely uniformly heats the wafer 1 held by a susceptor 40 (which will be described later).

A reflection plate 31 on which a titanium thin film is mirror-finished is horizontally supported by columns 32 standing on the support plate 28 below the heater 30 of the heating unit 27. The reflection plate 31 effectively reflects heat wave radiated from the heater 30 vertically upward. A plurality of thermocouples 33 as temperature sensors are disposed on the support plate 28 at appropriate distances from each other such as to project above the heater 30. The thermocouples 33 measure a temperature of the wafer 1 heated by the heater 30. Electric wires (not shown) of the heater 30 and the thermocouples 33 are connected to an external power supply or a controller through an opening of the support plate 28 and a hollow portion of the support shaft 26 from the heating unit 27.

A cylindrical rotation shaft 34 having a larger diameter than the support shaft 26 is concentrically disposed outside of the support shaft 26 of the insertion hole 25 of the bottom cap 15, and is inserted into the processing chamber 11 from below. The rotation shaft 34 is lifted and lowered together with the support shaft 26 by the lifting and lowering driving apparatus using an air cylinder or the like. A rotation drum 35 is concentrically disposed on an upper end of the rotation shaft 34 and horizontally fixed thereto, and is rotated by the rotation shaft 34. The rotation drum 35 comprises a doughnut-like flat-plate shaped rotation plate 36, and a cylindrical rotation cylinder 37. An inner peripheral portion of the rotation plate 36 is fixed to an upper end opening of the cylindrical rotation shaft 34, and a rotation cylinder 37 is concentrically fixed to an outer peripheral portion of the rotation plate 36.

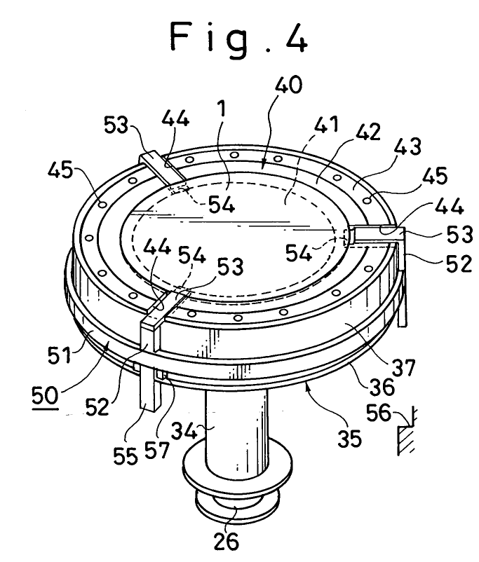

As shown in FIGS. 2 and 4 in detail, the susceptor 40 is put on an upper end of the rotation cylinder 37 of the rotation drum 35 such as to occlude the upper end opening of the rotation cylinder 37. The susceptor 40 comprises a disc-like central member 41, a ring-like first peripheral member 42 and second peripheral member 43, and these members are concentrically disposed such as to form one disc. Steps formed on adjacent outer peripheral side and inner peripheral side vertically engage each other such that the inner step is supported by the outer step.

The central member 41 is made of silicon carbide or aluminum nitride, and an outer diameter of the central member 41 is smaller than an outer diameter of the wafer 1. The first peripheral member 42 supporting the central member 41 at its outer side is made of silicon carbide or aluminum nitride and an inner diameter of the first peripheral member 42 is equal to the outer diameter of the central member 41, and an outer diameter thereof is larger than the outer diameter of the wafer 1. The second peripheral member 43 supporting the first peripheral member 42 at its outer side is made of quartz, an inner diameter is equal to the outer diameter of the first peripheral member 42, and an outer diameter thereof is slightly larger than the inner diameter of the rotation cylinder 37.

Upper surfaces of the first peripheral member 42 and the second peripheral member 43 are higher than an upper surface of the central member 41 by a height corresponding to the thickness of the wafer 1. That is, the upper surfaces of the first peripheral member 42 and the second peripheral member 43 are flush with the upper surface of the wafer 1 placed on the upper surface of the central member 41. The upper surfaces of the first peripheral member 42 and the second peripheral member 43 are radially formed with three guide grooves 44 in the circumferential direction. Engaging members 53 of a wafer lifting and lowering apparatus 50 (which will be described later) can slidably inserted into the guide grooves 44, respectively.

The second peripheral member 43 is formed with a plurality of nitrogen gas blowout ports 45 in the circumferential direction at equal distances from one another such as to vertically pass through the second peripheral member 43. The nitrogen gas blowout ports 45 equally blow out the nitrogen gas 4 supplied into the rotation drum 35 through the cylindrical hollow portion of the support shaft 26 toward the susceptor 40 over the entire circumference.

AB shown in FIGS. 2 and 4 in detail, the wafer lifting and lowering apparatus 50 is disposed on an outer side of the rotation drum 35 for lifting and lowering the wafer 1 as a substrate to be processed with respect to the susceptor 40 and the heating unit 27. That is, the wafer lifting and lowering apparatus 50 comprises a circular ring-like lifting and lowering ring 51, and the lifting and lowering ring 51 is concentrically disposed in the vicinity of an outer periphery of the rotation drum 35. Three columns 52 vertically stand upward at equal distances from one another in the circumferential direction. The three columns 52 are disposed at such location that the columns 52 do not hinder the transfer operation of the wafer 1 to and from the wafer carry in-out port 16. That is, the three 52 do not interfere with the tweezer 2 of the wafer transfer apparatus inserted into the wafer carry in-out port 16.

From the columns 52, the engaging members 53 are horizontally and radially projected inwardly. The engaging members 53 are detachably fitted into the guide grooves 44 from above. The engaging members 53 are formed at their tip ends with thin engaging claws 54, and the engaging claws 54 can engage an outer peripheral lower surface of the wafer 1 placed on the central member 41 of the susceptor 40 from below.

Three abutting members 55 are disposed on a lower end surface of the lifting and lowering ring 51 in the circumferential direction at equal distances from one another, and suspended vertically downward. Lower end surfaces of the abutting members 55 are opposed to a chamber-side abutting portion 56 formed in a shape of a step at a lower position than the wafer carry in-out port 16 on an inner peripheral surface of the lower cap 13 of the chamber 12. The abutting members 55 are fitted into guides 57 projected from an outer periphery of the rotation cylinder 37 with appropriate clearances, thereby positioning the lifting and lowering ring 51 with respect to the rotation drum 35 in the circumferential direction, and guiding the lifting and lowering operation.

Next, by explaining the operation of the single wafer-fed CVD apparatus having the above-described structure, a method for forming a CVD film according to the one embodiment of the present invention will be explained.

As shown in FIGS. 1 and 2, when the wafer 1 is transferred out, the rotation drum 35 and the heating unit 27 are lowered to the lower limit position by the rotation shaft 34 and the support shaft 26. Then, the abutting members 55 of the wafer lifting and lowering apparatus 50 abut against the chamber-side abutting portion 56 and thus, the lifting and lowering ring 51 is lifted with respect to the rotation drum 35. As the lifting and lowering ring 51 is lifted, the three engaging members 53 fixed to the lifting and lowering ring 51 support the wafer 1 from three directions to float up the wafer 1 from the susceptor 40.

If the wafer lifting and lowering apparatus 50 floats up the wafer 1 from the upper surface of the susceptor 40, since an insertion space is formed below the wafer 1, i.e., between the lower surface of the wafer 1 and the upper surface of the susceptor 40, the tweezer 2 of the wafer transfer apparatus is inserted into the insertion space of the wafer 1 from the wafer carry in-out port 16. At that time, the columns 52 supporting the three engaging members 53 do not interfere with the tweezer 2 of the wafer transfer apparatus inserted into the wafer carry in-out port 16.

As shown in FIG. 2, the tweezer 2 inserted below the wafer 1 is lifted, and the tweezer 2 transfers and receives the wafer 1. The tweezer 2 which received the wafer 1 moves the wafer carry in-out port 16 backward and transfers the wafer 1 out from the processing chamber 11. The wafer transfer apparatus which transferred out the wafer 1 by the tweezer 2 transfers the wafer 1 to a predetermined accommodating place (not shown) such as a vacant wafer cassette outside the processing chamber 11.

Thereafter, the wafer transfer apparatus receives another wafer 1 on which a film is formed by the tweezer 2 from a predetermined accommodating place (not shown) such as a wafer cassette, and transfers the wafer 1 from the wafer carry in-out port 16 to the processing chamber 11. As shown in FIG. 2, the tweezer 2 transfers the wafer 1 to a position where a center of the wafer 1 coincides with a center of the susceptor 40 above the three engaging members 53. If the tweezer 2 transferred the wafer 1 to the predetermined position, the tweezer 2 is slightly lowered and transfers the wafer 1 to the three engaging members 53. At that time, the thin engaging claws 54 on the tip ends of the three engaging members 53 slightly engage the outer periphery of the wafer 1 from below to receive the wafer 1.

The tweezer 2 which transferred the wafer 1 to the wafer lifting and lowering apparatus 50 in this manner goes out from the processing chamber 11 through the wafer carry in-out port 16. When the tweezer 2 went out from the processing chamber 11, the wafer carry in-out port 16 is closed by the gate valve 17.

As shown in FIG. 3, if the gate valve 17 is closed, the rotation drum 35 and the heating unit 27 are lifted by the rotation shaft 34 and the support shaft 26 with respect to the processing chamber 11. In the initial lifting stage of the rotation drum 35, since the three abutting members 55 are placed on the chamber-side abutting portion 56, the wafer lifting and lowering apparatus 50 does not follow the upward movement of the rotation drum 35 and remains in its stopped state. That is, as the rotation drum 35 is lifted, the wafer 1 supported by the wafer lifting and lowering apparatus 50 is relatively lowered with respect to the susceptor 40.

As shown in FIG. 4, as the rotation drum 35 is lifted, if the wafer 1 is relatively lowered to a position of the susceptor 40, the three engaging members 53 are fitted into the guide grooves 44 formed on the upper surface of the rotation drum 35, and the wafer 1 supported below is placed on the susceptor 40. In a state in which the wafer 1 is placed on the susceptor 40, the upper surface of the first peripheral member 42, the upper surface of the second peripheral member 43 and the upper surfaces of the three engaging members 53 are flush with each other.

As shown in FIG. 3, after the three engaging members 53 are fitted into the guide grooves 44 formed in the upper surface of the rotation drum 35, the wafer lifting and lowering apparatus 50 is lifted by the rotation drum 35, the processing chamber 11 is lifted together. As they are lifted, the abutting members 55 are separated from the chamber-side abutting portion 56.

The wafer 1 placed on the susceptor 40 is heated by the heater 30, and a temperature of the heater 30 and a temperature of the wafer 1 are measured by the thermocouples 33. A heating amount of the heater 30 is feedback controlled in accordance with the measured result of the thermocouples 33. At that time, since the thin engaging claws 54 of the three engaging members 53 are in slight contact with the outer periphery of the wafer 1, this does not affect the heating operation of the heater 30, and the temperature distribution of the wafer is entirely uniform irrespective of existence of the engaging members 53. Further, since the outermost peripheral second peripheral member 43 is made of quartz, it is possible to prevent the heat of the wafer 1 from escaping outside.

The rotation drum 35 and the heating unit 27 lifts the processing chamber 11 by the rotation shaft 34 and the support shaft 26, and stops lifting the processing chamber at the height at which the upper surface of the wafer 1 approach the lower surface of the plate 22.

The exhaust port 18 is evacuated by the vacuum exhaust apparatus, and the rotation drum 35 is rotated by the rotation shaft 34. When the exhaust amount of the exhaust port 18 and the rotation of the rotation drum 35 are stabilized, the processing gas 3 is introduced into the gas introducing ports 21. The nitrogen gas 4 is blown out from the nitrogen gas blowout ports 45 uniformly.

The processing gas 3 introduced into the gas introducing ports 21 flows into the gas reservoir 24 by the exhausting force of the exhaust port 18 acting on the gas reservoir 24, and disperse radially outward, and flows from the blowout ports 23 of the plate 22 substantially uniformly, and the processing gas 3 blown out like shower from the blowout ports 23 is drawn into the exhaust port 18 and exhausted.

At that time, since the wafer 1 on the susceptor 40 supported by the rotation drum 35 is rotating, the processing gas 3 blown out like shower from the blowout ports 23 is brought into contact with the entire surface of the 1 uniformly. Further, since the upper surface of the wafer 1 and the upper surface of the outer side susceptor 40 are flush with each other, the flow of the processing gas 3 is prevented from being disturbed and is controlled uniformly. Here, since a film formation rate by the thermochemical reaction of the processing gas 3 depends on a contact amount of the processing gas 3 with respect to the wafer 1, if the processing gas 3 is in contact with the entire surface of the wafer 1 uniformly, the film thickness distribution and the film quality distribution of the CVD film formed on the wafer 1 by the processing gas 3 becomes uniform over the entire surface of the wafer 1.

Further, since the heating unit 27 is supported by the support shaft 26 and is not rotated, the temperature distribution of the wafer 1 which is heated by the heating unit 27 while being rotated by the rotation drum 35 is controlled uniformly in the circumferential direction. Here, since the film formation rate by the thermochemical reaction largely depends on the temperature distribution, if the temperature of the wafer 1 is uniformly over the entire surface, the film thickness distribution and the film quality distribution of the CVD film formed on the wafer 1 by the thermochemical reaction is controlled uniformly over the entire surface of the wafer 1.

The nitrogen gas 4 is blown out from the nitrogen gas blowout ports 45 and the rotation drum 35 is filled with the nitrogen gas 4. Therefore, the processing gas 3 is prevented from entering the rotation drum 35. Thus, it is possible to prevent the heater 30 of the heating unit 27 from being adversely deteriorated by the processing gas 3 which entered the rotation drum 35, and to prevent the processing gas 3 from adversely adhering the reflection plate 31 or the thermocouples 33 to deteriorate the functions thereof.

When the CVD film is formed uniformly over the entire surface of the wafer 1 in the above-described manner and a predetermined processing time is elapsed, as shown in FIG. 1, the rotation drum 35 and the heating unit 27 are lowered to the transfer position by the rotation shaft 34 and the support shaft 26. On the way to the transfer position, since the three abutting members 55 of the wafer lifting and lowering apparatus 50 abut against the chamber-side abutting portion 56, the wafer lifting and lowering apparatus 50 floats up the wafer 1 from the susceptor 40 in the above-described operation.

Thereafter, by repeating the above-described operations, the CVD films are formed on the wafers 1 by the single wafer-fed CVD apparatus 10 one by one.

According to the above embodiment, the following effects can be obtained.

(1) By rotating the susceptor 40 holding the wafer 1, the processing gas 3 can be brought into contact with the entire surface of the wafer 1 uniformly. Therefore, it is possible to control the film thickness distribution and the film quality distribution of the CVD film formed on the wafer 1 by the processing gas 3.

(2) The susceptor 40 holding the wafer 1 is rotated and the heating unit 27 is stopped. Therefore, it is possible to uniformly control, in the circumferential direction, the temperature distribution of the wafer 1 heated by the heating unit 27 while the wafer 1 is rotated by the susceptor 40. Thus, the film thickness distribution and the film quality distribution of the CVD film formed on the wafer 1 by the thermochemical reaction can be controlled uniformly over the entire surface of the wafer 1.

(3) Since the heating unit 27 is not rotated, the heater 30 and the thermocouples 33 can be disposed in the heating unit 27, and electric wires for the heater 30 and the thermocouples 33 can easily be provided in the heating unit 27.

(4) When the wafer 1 is transferred to and from the susceptor 40, the wafer lifting and lowering apparatus 50 lifts the wafer 1 to form the insertion space between the lower surface of the wafer 1 and the lower surface of the susceptor 40. Therefore, the tweezer 2 can be inserted into the insertion space and thus, the wafer 1 can be mechanically supported by the tweezer 2 from below, and the wafer 1 can be transferred by the mechanical wafer transfer apparatus.

(5) For the reason of the paragraph (4), it is unnecessary to employ the vacuum absorption type wafer transfer apparatus using the vacuum absorption and holding apparatus or the static absorption type wafer transfer apparatus using the static absorption and holding apparatus having a complicated structure as the wafer transfer apparatus. Therefore, it is possible to largely reduce the producing cost of the single wafer-fed CVD apparatus. Further, the application range of the invention is not limited, and the invention can be applied to general substrate processing apparatuses such as normal CVD apparatuses, decompression CVD apparatuses and plasma CVD apparatuses. Since a vacuum absorption and holding apparatus including a non-contact type vacuum absorption and holding apparatus holds a wafer by a pressure difference between upper and lower surfaces of the wafer, the vacuum absorption and holding apparatus can not be used in a decompression chamber. Further, a the static absorption and holding apparatus absorbs a wafer utilizing static electricity, the apparatus can not be used when there is a possibility of electrostatic destroy, and a diselectrifying apparatus or an antistatic apparatus is required, and a structure and management of the apparatus become complicated.

(6). The wafer lifting and lowering apparatus 50 is disposed outside the rotation drum 35, the three engaging members 53 slightly engage the outer periphery of the wafer 1 to support the wafer 1 from below. Therefore, effect exerted on heating of the heating unit 27 of the wafer lifting and lowering apparatus 50 can be suppressed and thus, the temperature distribution of the wafer 1 can be controlled entirely uniformly over the entire wafer 1 irrespective of existence of the wafer lifting and lowering apparatus 50.

(7) Since the second peripheral, member 43 located at outermost peripheral portion of the susceptor 40 is made of quartz, it is possible to prevent the heat of the wafer 1 from escaping outside. Therefore, it is possible to control the temperature distribution uniformly over the entire wafer 1.

(8) Since the upper surface of the outer peripheral portion of the susceptor 40 and the upper surface of the wafer 1 on the susceptor 40 are flush with each other, it is possible to prevent the flow of the processing gas 3 from disturbing. Therefore, the film thickness distribution and the film quality distribution of the CVD film formed on the wafer 1 by the thermochemical reaction can be controlled uniformly over the entire surface of the wafer 1.

(9) The plurality of nitrogen gas blowout ports 45 are formed in the second peripheral member 43 of the outermost periphery of the susceptor 40 in the circumferential direction at equal distances from one another, the nitrogen gas 4 is supplied to the rotation drum 35 supporting the susceptor 40 to blow out the nitrogen gas 4 from the nitrogen gas blowout ports 45. With this arrangement, it is possible to prevent the processing gas 3 from entering the rotation drum 35 and thus, it is possible to prevent the heater 30 of the heating unit 27 from being adversely deteriorated by the processing gas 3 which entered the rotation drum 35, and to prevent the processing gas 3 from adversely adhering the reflection plate 31 or the thermocouples 33 to deteriorate the functions thereof.

(10) When the wafer is transferred to and from the susceptor 40, the susceptor 40 and the heating unit 27 are lifted and lowered while keeping a distance therebetween constant. With this arrangement, it is possible to maintain the heated state of the susceptor 40 constant and thus, the stability of the temperature can be enhanced.

Although the abutting members 55 of the wafer lifting and lowering apparatus 50 abut against the step-like abutting portion 56 formed on the side wall of the lower cap 13 of the chamber 12 in the above embodiment, the abutting members 55 may abut against a bottom surface (upper surface of the bottom cap 15) of the processing chamber 11.

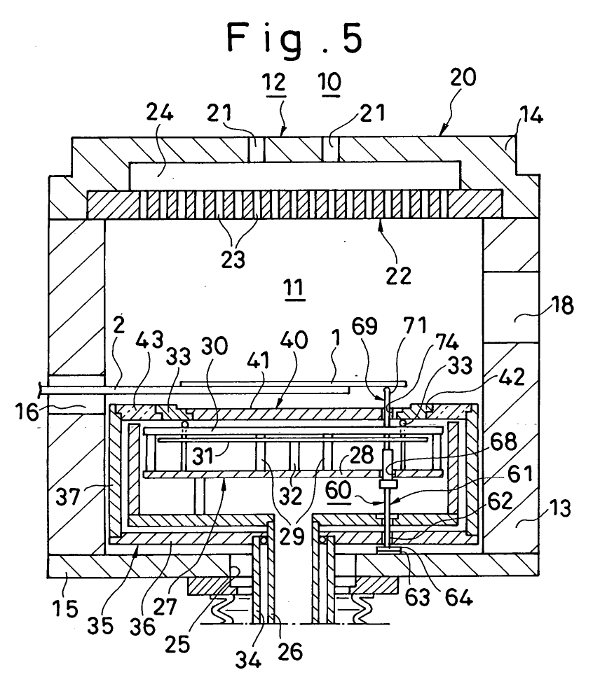

Next, a second embodiment of the present invention will be explained with reference to FIGS. 5 to 10.

The second embodiment is different from the first embodiment mainly in that the wafer lifting and lowering apparatus for lifting and lowering the wafer as a substrate to be processed with respect to the susceptor and the heating unit to disposed inside the rotation drum.

That is, as shown in FIGS. 5 to 9B, a wafer lifting and lowering apparatus 60 disposed inside the rotation drum includes three push-up pins (fixed pins, hereinafter) 61 fixed on a bottom wall (upper surface of the bottom cap 15) vertically upwardly, and the three fixed pins 61 are disposed at locations where the pins 61 do not hinder the transferring operation of the wafer 1 to and from the wafer carry in-out port 16. That is, the three fixed pins 61 are disposed at locations where the pins 61 do not interfere with the tweezer 2 of the wafer transfer apparatus to be inserted into the wafer carry in-out port 16.

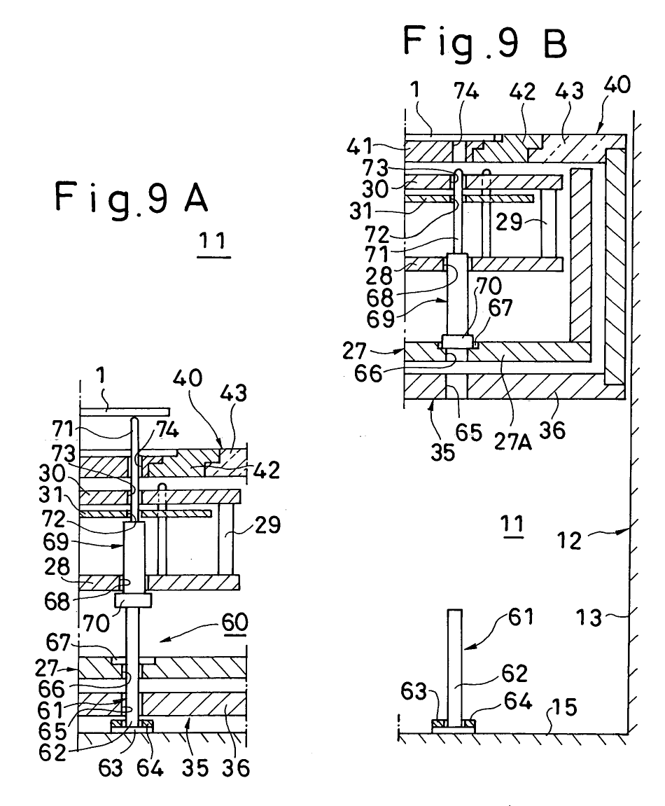

As shown in FIGS. 9A and 9B in detail, each of the fixed pins 61 is formed into a thumbtack having a long pin portion 62 and a flange 63, and a lower surface of the flange 63 abuts, against the upper surface of the bottom cap 15 and the pin 61 stands vertically upwardly. A seat plate 64 is fitted around an outer periphery of the pin portion 62, and the seat plate 64 is placed on an upper surface of the flange 63. A length of the pin portion 62 is set such that the length corresponds to a push-up amount of the wafer from the susceptor. A thickness of the pin portion 62 is set such that the pin portion 62 can be inserted into an insertion hole 65 formed in the rotation plate 36 of the rotation drum 35 and into an insertion hole 66 formed in a casing 27A of the heating unit 27.

The three insertion holes (rotation-side insertion holes, hereinafter) formed in the rotation plate 36 of the rotation drum 35 are respectively opposed to the three fixed pins 61 at locations where the rotation drum 35 is lifted and lowered. The three insertion holes (fixed insertion holes, hereinafter) 66 formed in the casing 27A of the heating unit 27 are respectively opposed to the three fixed pins 61. That is, at locations where the rotation drum 35 is lifted and lowered, the three fixed pins 61 are inserted through the three rotation-side insertion holes 65 and the three fixed insertion holes 66, respectively.

Three guide holes 68 are formed in the support plate 28 of the heating unit 27 such as to be opposed to the fixed insertion holes 66, respectively. Pins (movable pins, hereinafter) 69 for pushing up the wafer from the susceptor are vertically slidably fitted into the guide holes 68. Each of the movable pins 69 includes a large-diameter portion and a small-diameter portion and formed into a round rod shape, and a lower end of the large-diameter portion is formed with a flange 70. The flange 70 is opposed to a bottom surface of a support hole 67 formed in an upper end of the fixed insertion hole 66. The small-diameter portion of the upper end of the movable pin 69 is formed with a push-up portion 71. The push-up portion 71 pass through the reflection plate 31, the heater 30 and the susceptor 40.

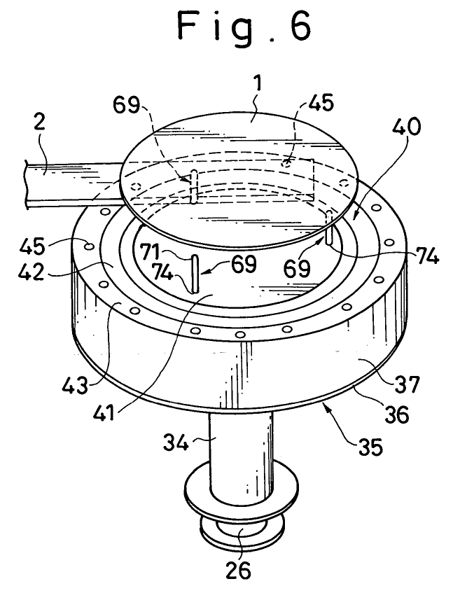

That is, at three locations respectively opposed to the three movable pins 69 at the reflection plate 31, the heater 30 and the susceptor 40, insertion holes 72, 72 and 74 are formed such that the push-up portions 71 can be inserted into the insertion holes 72, 72 and 74. As shown in FIG. 6, the three insertion holes 74 formed in the susceptor 40 are positioned at an outer peripheral portion of the central member 41 of the susceptor 40, and the three insertion holes 74 disposed in the circumferential direction are opposed to the three fixed pins 61. Therefore, the insertion holes 74 do not interfere with the tweezer 2 of the wafer transfer apparatus to be inserted into the wafer carry in-out port 16.

Next, by explaining the operation of the single wafer-fed CVD apparatus having the above-described structure, a method for forming a CVD film according to the one embodiment of the present invention will be explained.

As shown in FIG. 5, when the wafer 1 is transferred out, if the rotation drum 35 and the heating unit 27 are lowered to the lower limit position by the rotation shaft 34 and the support shaft 26, the three movable pins 69 of the wafer lifting and lowering apparatus 60 respectively abut against the opposed fixed pins 61, and are lifted with respect to the rotation drum 35 and the heating unit 27. The lifted three movable pins 69 support the wafer 1 from below and float up the wafer 1 from the susceptor 40.

As shown in FIG. 9A, the wafer lifting and lowering apparatus 60 floats up the wafer 1 from the upper surface of the susceptor 40, since an insertion space is formed below the wafer 1, i.e., between the lower surface of the wafer 1 and the upper surface of the susceptor 40, the tweezer 2 of the wafer transfer apparatus is inserted into the insertion space of the wafer 1 from the wafer carry in-out port 16. At that time, as shown in FIG. 6, three movable pins 69 do not interfere with the tweezer 2 of the wafer transfer apparatus inserted into the wafer carry in-out port 16.

As shown in FIG. 6, the tweezer 2 inserted below the wafer 1 is lifted, and the tweezer 2 transfers and receives the wafer 1. The tweezer 2 which received the wafer 1 moves the wafer carry in-out port 16 backward and transfers the wafer 1 out from the processing chamber 11. The wafer transfer apparatus which transferred out the wafer 1 by the tweezer 2 transfers the wafer 1 to a predetermined accommodating place (not shown) such as a vacant wafer cassette outside the processing chamber 11.

Thereafter, the wafer transfer apparatus receives another wafer 1 on which a film is formed by the tweezer 2 from a predetermined accommodating place (not shown) such as a wafer cassette, and transfers the wafer 1 from the wafer carry in-out port 16 to the processing chamber 11. The tweezer 2 transfers the wafer 1 to a position where a center of the wafer 1 coincides with a center of the susceptor 40 above the three movable pins 69. If the tweezer 2 transferred the wafer 1 to the predetermined position, the tweezer 2 is slightly lowered and transfers the wafer 1 to the three movable pins 69. At that time, since tip ends of the three movable pins 69 are formed small in diameter, if the movable pins 69 are brought into slight contact with the lower surface of the wafer 1, the movable pins 69 receive the wafer 1.

The tweezer 2 which transferred the wafer 1 to the wafer lifting and lowering apparatus 60 in this manner goes out from the processing chamber 11 through the wafer carry in-out port 16. When the tweezer 2 went out from the processing chamber 11, the wafer carry in-out port 16 is closed by the gate valve 17.

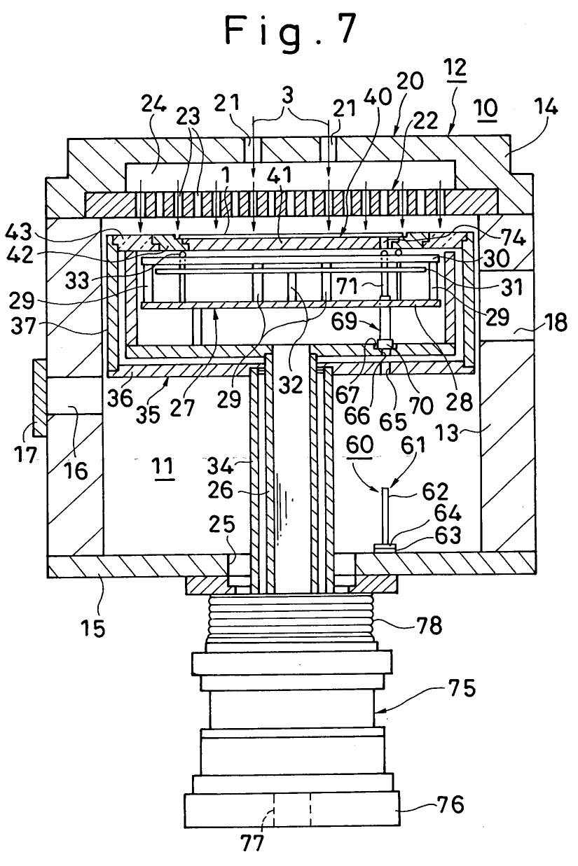

As shown in FIG. 7, if the gate valve 17 is closed, the rotation drum 35 and the heating unit 27 are lifted by the rotation shaft 34 and the support shaft 26 with respect to the processing chamber 11. In the initial lifting stage of the rotation drum 35, since the three movable pins 69 are placed on the fixed pins 61, the three movable pins 69 are gradually lowered relatively with respect to the rotation drum 35 as the rotation drum 35 is lifted.

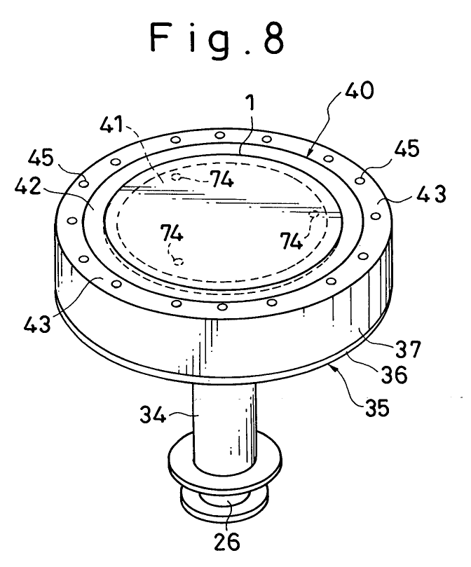

As shown in FIG. 9B, if the three movable pins 69 are separated from the fixed pins 61, the three movable pins 69 are pulled into the insertion holes 74 of the susceptor 40, and the movable pins 69 supporting the wafer 1 from below place the wafer 1 onto the susceptor 40. In a state in which the wafer 1 is moved onto the susceptor 40, the three movable pins 69 are pulled out downward from the insertion holes 74 of the susceptor 40 and separated from the insertion holes 74. Further, as shown in FIG. 8, the upper surface of the wafer 1, the upper surface of the first peripheral member 42 and the upper surface of the second peripheral member 43 are flush with each other.

The wafer 1 moved onto the susceptor 40 is heated by the heater 30, and a temperature of the heater 30 and a temperature of the wafer 1 are measured by the thermocouples 33. A heating temperature of the heater 30 is feedback controlled in accordance with the measured result of the thermocouples 33. At that time, since the insertion holes 74 through which the three movable pins 69 are to be inserted are only opened slightly at the outer periphery of the wafer 1, this does not affect the heating operation of the heater 30, and the temperature distribution of the wafer 1 is entirely uniform respective of existence of the three insertion holes 74.

As shown in FIG. 7, the rotation drum 35 and the heating unit 27 lifts the processing chamber 11 by the rotation shaft 34 and the support shaft 26, and stops lifting the processing chamber 11 at the height at which the upper surface of the wafer 1 approach the lower surface of the plate 22.

The exhaust port 18 is evacuated by the vacuum exhaust apparatus, and the rotation drum 35 is rotated by the rotation shaft 34. When the exhaust amount of the exhaust port 18 and the rotation of the rotation drum 35 are stabilized, the processing gas 3 is introduced into the gas introducing ports 21. The processing gas 3 introduced into the gas introducing ports 21 flows into the gas reservoir 24 by the exhausting force of the exhaust port 18 acting on the gas reservoir 24, and disperse radially outward, and flows from the blowout ports 23 of the plate 22 substantially uniformly, and blows out like shower toward the wafer 1. The processing gas 3 blown out like shower from the blowout ports 23 is drawn into the exhaust port 18 and exhausted.

At that time, since the wafer 1 on the susceptor 40 supported by the rotation drum 35 is rotating, the processing gas 3 blown out like shower from the blowout ports 23 is brought into contact with the entire surface of the 1 uniformly. Further, since the upper surface of the wafer 1 and the upper surface of the outer side susceptor 40 are flush with each other, the flow of the processing gas 3 is prevented from being disturbed and is controlled uniformly. Because the processing gas 3 is in contact with the entire surface of the wafer 1 uniformly, the film thickness distribution and the film quality distribution of the CVD film formed on the wafer 1 by the processing gas 3 becomes uniform over the entire surface of the wafer 1.

Further, since the heating unit 27 is supported by the support shaft 26 and is not rotated, the temperature distribution of the wafer 1 which is heated by the heating unit 27 while being rotated by the rotation drum 35 is controlled uniformly in the circumferential direction. If the temperature of the wafer 1 is uniformly over the entire surface, the film thickness distribution and the film quality distribution of the CVD film formed on the wafer 1 by the thermochemical reaction is controlled uniformly over the entire surface of the wafer 1.

Since the three movable pins 69 are supported by the guide holes 68 and the support holes 67 of the heating unit 27, the movable pins 69 are stopped together with the heating unit 27. Further, since the fixed pins 61 are fixed to the bottom cap 15 of the chamber 12, the fixed pins 61 are stopped.

When the CVD film is formed uniformly over the entire surface of the wafer 1 in the above-described manner and a predetermined processing time is elapsed, the rotation of the rotation drum 35, is stopped at a phase corresponding to a predetermined transfer position. Next, as shown in FIG. 1, the rotation drum 35 and the heating unit 27 are lowered to the transfer position by the rotation shaft 34 and the support shaft 26. On the way to the transfer position, since the three movable pins 69 of the wafer lifting and lowering apparatus 60 abut against the fixed pins 61, the wafer lifting and lowering apparatus 60 floats up the wafer 1 from the susceptor 40 in the above-described operation.

Thereafter, by repeating the above-described operations, the CVD films are formed on the wafers 1 by the single wafer-fed CVD apparatus 10 one by one.

As explained above, in the second embodiment, when the wafer 1 is transferred to and from the susceptor 40, the wafer lifting and lowering apparatus 60 lifts the wafer 1 to form the insertion space between the lower surface of the wafer 1 and the lower surface of the susceptor 40. Therefore, the tweezer 2 can be inserted into the insertion space and thus, the wafer 1 can be mechanically supported by the tweezer 2 from below. That is, in the second embodiment also, the wafer 1 can be transferred to and from the susceptor 40 by the mechanical wafer transfer apparatus.

Further, by rotating the susceptor 40 holding the wafer 1, the processing gas 3 can be brought into contact with the entire surface of the wafer 1 uniformly. Therefore, it is possible to control the film thickness distribution and the film quality distribution of the CVD film formed on the wafer by the processing gas 3.

The susceptor 40 holding the wafer 1 is rotated and the heating unit 27 is stopped. Therefore, it is possible to uniformly control, in the circumferential direction, the temperature distribution of the wafer 1 heated by the heating unit 27 while the wafer is rotated by the susceptor 40. Thus, the film thickness distribution and the film quality distribution of the CVD film formed on the wafer 1 by the thermochemical reaction can be controlled uniformly over the entire surface of the wafer 1.

Since the heating unit 27 is not rotated, the heater 30 and the thermocouples 33 can be disposed in the heating unit 27, and electric wires for the heater 30 and the thermocouples 33 can easily be provided in the heating unit 27.

Since the wafer lifting and lowering apparatus 60 for lifting and lowering the wafer 1 with respect to the susceptor 40 is disposed on the inner side of the susceptor 40, it is possible to prevent the wafer lifting and lowering apparatus 60 from projecting outside the rotation drum 35, and to prevent the volume of the processing chamber 11 from being increased.

When the wafer 1 is transferred to and from the susceptor 40, the susceptor 40 and the heating unit 27 are lifted and lowered while keeping a distance therebetween constant. With this arrangement, it is possible to maintain the heated state of the susceptor 40 constant and thus, the stability of the temperature can be enhanced.

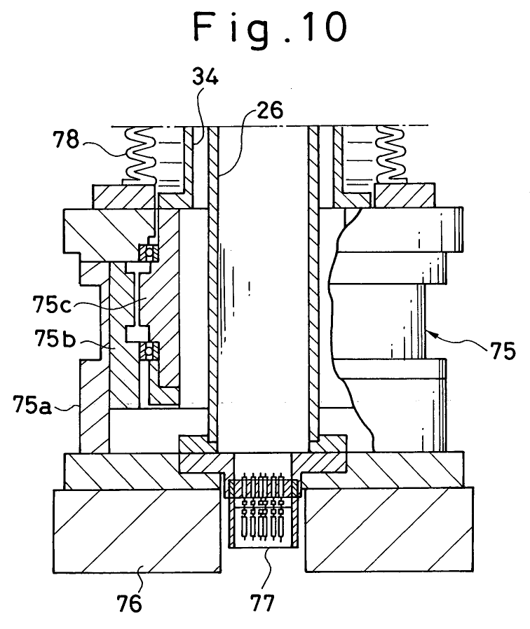

Next, one embodiment of the rotation driving apparatus for rotating a rotation shaft while fixing a support shaft will be explained with reference to FIG. 10.

The rotation driving apparatus shown in FIG. 10 includes a hollow shaft electric motor (motor, hereinafter) 75. A hollow output shaft of the motor 75 is formed as the rotation shaft 34 for rotating the rotation drum 35. A housing 75a of the motor 75 comprises an air cylinder apparatus or the like, and the housing 75a is stationarily disposed vertically upward on an elevator lifting and lowering stage 76. Only a portion of the elevator lifting and lowering stage 76 is illustrated in the drawing. The housing 75a is lifted and lowered with respect to the chamber 12 of the single wafer-fed CVD apparatus by the elevator lifting and lowering stage 76. A stator 75b is fixed to an inner peripheral surface of the housing 75a, and an armature 75c of the motor 75 is concentrically disposed on inner side of the stator 75b with an air gap interposed therebetween. The armature 75c is rotatably supported by the housing 75a. The rotation shaft 34 which is a hollow output shaft is fixed to the armature 75c such that the rotation shaft 34 rotates in unison with the armature 75c. The support shaft 26 is disposed on the center line of the rotation shaft 34 and fixed to the housing 75a.

A hermetic seal 77 for fluidly isolating the hollow portion of the support shaft 26, i.e., inside and outside of the processing chamber 11 is mounted to a lower end opening of the support shaft 26. Electric wires (not shown) of the heater 30 and the thermocouples 33 are pulled out from the hollow portion of the support shaft 26 through the hermetic seal 77. Bellows 78 for sealing the insertion hole 25 of the chamber 12 is concentrically disposed on the outer side of the rotation shaft 34. Upper and lower ends of the bellows 78 are respectively fastened to a lower surface of the bottom cap 15 of the chamber 12 and an upper surface of the flange of the rotation shaft 34.

According to the rotation driving apparatus having the above structure, since the rotation shaft 34 can be rotated while fixing the support shaft 26, if the heating unit 27 is supported by the support shaft 26 and the rotation drum 35 is supported by the rotation shaft 34, it is possible to rotate the susceptor 40, i.e., the wafer 1 while the heating unit 27 is stopped.

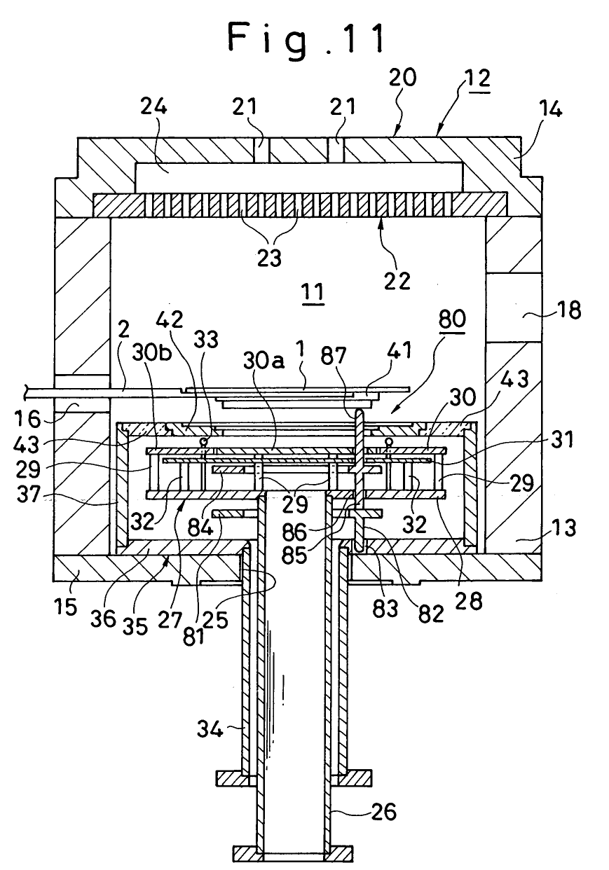

Next, a third embodiment of the present invention will be explained with reference to FIGS. 11 to 15C.

The third embodiment is different from the first embodiment mainly in that the wafer lifting and lowering apparatus is disposed inside the rotation drum, the wafer is lifted and lowered through a central member of the susceptor, and the heater is divided.

That is, as shown in FIGS. 11 to 14, the wafer lifting and lowering apparatus 80 disposed inside the rotation drum includes a circular lifting and lowering ring 81. The lifting and lowering ring 81 is disposed on the rotation plate 36 of the rotation drum 35 concentrically with the support shaft 26. A plurality of (three, in this embodiment) push-up pins (rotation-side pins, hereinafter) 82 are vertically downwardly projected on a lower surface of the lifting and lowering ring (rotation-side ring, hereinafter) 81 at equal distances from one another in the circumferential direction. Movable pins 69 are disposed on the rotation plate 36 concentrically with the rotation shaft 34 and slidably fitted into vertically formed guide holes 83 respectively.

Lengths of the movable pins 69 are set equally so as to push up the rotation-side ring 81 horizontally, and the lengths correspond to the pushing-up amount of the wafer from the susceptor. Lower ends of the movable pins 69 are opposed to the bottom surface of the processing chamber 11, i.e., the upper surface of the bottom cap 15 such that the movable pins 69 can be brought into and out of contact with the bottom surface of the processing chamber 11, i.e., the upper surface of the bottom cap 15.

A circular second lifting and lowering ring (heater-side ring, hereinafter) 84 is disposed on the support plate 28 of the heating unit 27 concentrically with the support shaft 26. A plurality of (three, in the present embodiment) push-up pins (heater-side pins, hereinafter) 85 are disposed on a lower surface of the heater-side ring 84 at equal distances from one another in the circumferential direction, and the push-up pins 85 are projecting vertically downward. The heater-side pins 85 are disposed on the support plate 28 concentrically with the support shaft 26 and slidably fitted into the guide holes 86 formed in the vertical direction.

Lengths of the heater-side pins 85 are set equal to each other such as to push up the heater-side ring 84 horizontally, and lower ends of the heater-side pins 85 are opposed to an upper surface of the rotation-side ring 81 with an appropriate air gas interposed therebetween. That is, when the rotation drum 35 is rotated, the heater-side pins 85 do not interfere with the rotation-side ring 81.

A plurality of (three, in the present embodiment) push-up pins (push-up portions, hereinafter) 87 are vertically upwardly projecting from an upper surface of the heater-side ring 84 at equal distances from one another in the circumferential direction. Upper ends of the push-up portions 87 pass through the reflection plate 31, the heater 30 and the susceptor 40 and are opposed to a lower surface of the central member 41 of the susceptor 40. Lengths of the push-up portions 87 are set equal to each other such as to push up the central member 41 horizontally. In a state in which the heater-side ring 84 sits on the support plate 28, an upper end of the heater-side ring 84 is opposed to an upper surface of the central member 41 with an appropriate air gap therebetween. That is, the push-up portions 87 do not interfere with the susceptor 40 when the rotation drum 35 rotates.

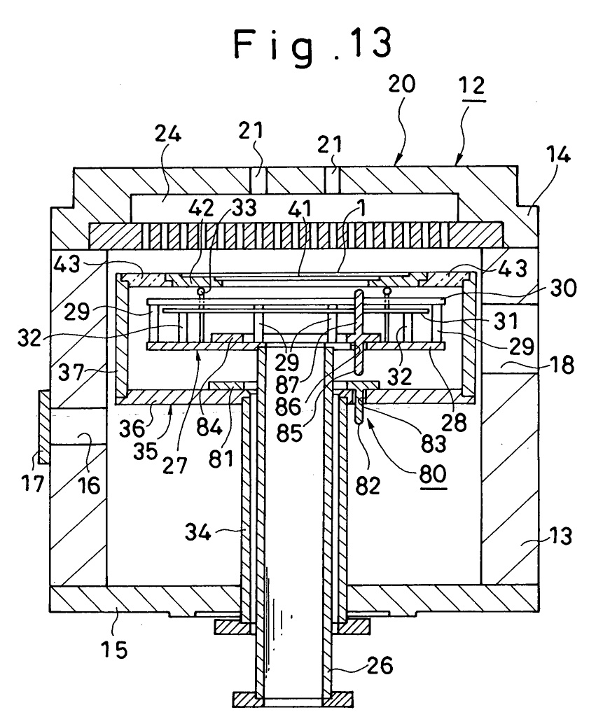

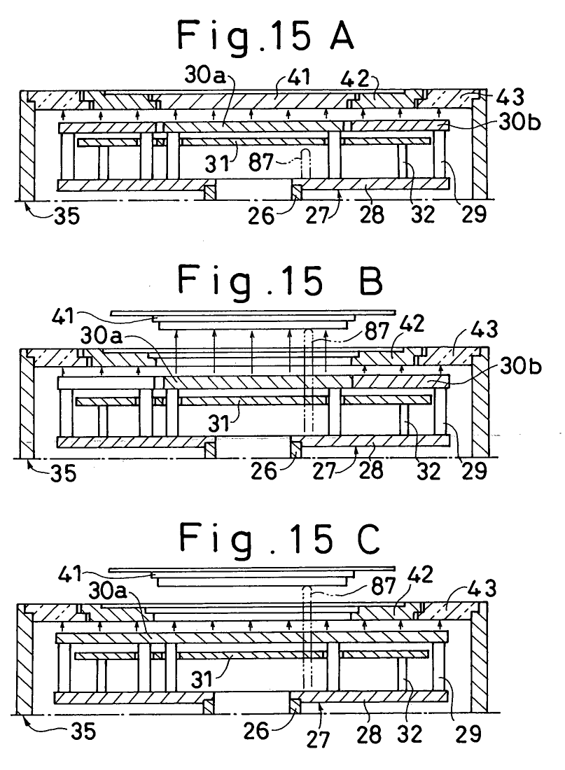

In FIG. 13, for the sake of expediency of illustration, the upper ends of the push-up portions 87 are located on the upper side of the heater 30, but as shown with phantom line in FIG. 15A, it is preferable that the upper ends of the push-up portions 87 are located below the heater 30 and the reflection plate 31 in view of heating effect of the heating unit 27. That is, if the push-up portions 87 are projecting above the heater 30 and the reflection plate 31, there is an adverse possibility that hot wires of the heater 30 and the reflection plate 31 are shielded.

As shown in FIGS. 15A to 15C, in the present embodiment, the heater 30 of the heating unit 27 is divided into a central heater member 30a corresponding to the central member 41 of the susceptor 40 and a peripheral heater member 30b corresponding to the first peripheral member 42 and the second peripheral member 43 of the susceptor 40. Outputs of the central heater member 30a and the peripheral heater member 30b can be controlled independently.

Next, by explaining the operation of the single wafer-fed CVD apparatus having the above-described structure, a method for forming a CVD film according to the one embodiment of the present invention will be explained.

As shown in FIG. 11, when the wafer 1 is transferred out, if the rotation drum 35 and the heating unit 27 are lowered to the lower limit position by the rotation shaft 34 and the support shaft 26, the lower ends of the rotation-side pins 82 of the wafer lifting and lowering apparatus 80 abut against the bottom surface of the processing chamber 11, i.e., the upper surface of the bottom cap 15. Therefore, the rotation-side ring 81 is relatively lifted with respect to the rotation drum 35 and the heating unit 27. The lifted rotation-side ring 81 pushes up the heater-side pins 85, and thereby pushing up the heater-side ring 84. If the heater-side ring 84 is pushed up, the three push-up portions 87 standing on the heater-side ring 84 support the central member 41 of the susceptor 40 from below, and float up the central member 41 from the first peripheral member 42 and the second peripheral member 43. Since the central portion of the wafer 1 is placed on the central member 41, the wafer 1 is floated up.

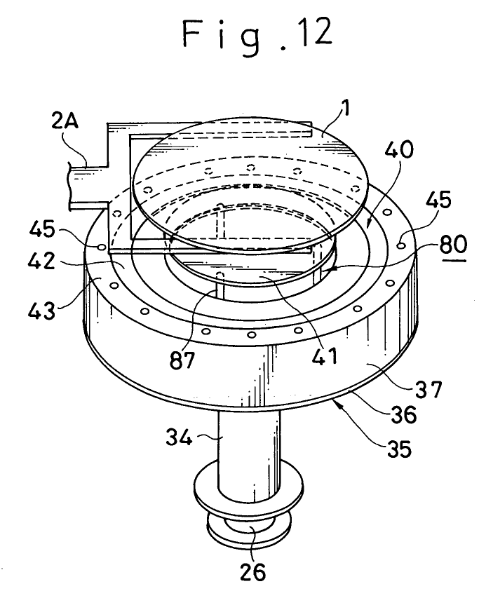

As shown in FIG. 12, when the wafer lifting and lowering apparatus 80 floats up the wafer 1 from the upper surface of the susceptor 40, the insertion space is formed below the wafer 1, i.e., between the lower surface of the wafer 1 and the upper surface of the susceptor 40. Therefore, a fork-like tweezer 2A of the wafer transfer apparatus is inserted into the insertion space of the wafer 1 from the wafer carry in-out port 16. At that time, since the central portion of the wafer 1 is supported by the central member 41, the fork-like tweezer 2A shown in FIG. 12 is used. That is, the tweezer 2A does not interfere with the central member 41 of the central portion of the wafer 1.

As shown in FIG. 2, the tweezer 2A inserted below the wafer 1 is lifted, and the tweezer 2A transfers and receives the wafer 1. At this time, the fork-like tweezer 2A receives an outer peripheral portion of the lower surface of the wafer 1. The tweezer 2 which received the wafer 1 moves the wafer carry in-out port 16 backward and transfers the wafer 1 out from the processing chamber 11. The wafer transfer apparatus which transferred out the wafer 1 by the tweezer 2A transfers the wafer 1 to a predetermined accommodating place (not shown) such as a vacant wafer cassette outside the processing chamber 11.

Thereafter, the wafer transfer apparatus receives another wafer 1 on which a film is formed by the tweezer 2A from a predetermined accommodating place (not shown) such as a wafer cassette, and transfers the wafer 1 from the wafer carry in-out port 16 to the processing chamber 11. The tweezer 2A transfers the wafer 1 to a position where a center of the wafer 1 coincides with a center of the central member 41 above the central member 41 of the susceptor 41. If the tweezer 2A transferred the wafer 1 to the predetermined position the tweezer 2A is slightly lowered and transfers the wafer 1 to the central member 41.

Since a temperature of the wafer 1 which was just transferred in is low, if the wafer 1 is moved, a temperature of the central member 41 is lowered. As shown in FIG. 15C, if the heater 30 is not divided and the if the susceptor 40 is uniformly heated entirely with the same output, the central member 41 cooled by the wafer 1 is lowered as it is and heated uniformly with the first peripheral member 42 and the second peripheral member 43. Therefore, the central portion of the wafer 1 becomes lower in temperature than the peripheral portion of the wafer 1 by a temperature corresponding to the cooled central member 41, and the temperature distribution of the wafer 1 becomes non-uniform. As a result, the film thickness distribution and the film quality distribution of the CVD film formed on the wafer 1 become non-uniform.

In the present embodiment, as shown in FIG. 15B, when the central member 41 is lifted to receive the wafer 1, the output of the central heater member 30a of the divided heater 30 is increased to heat the central member 41 to a higher temperature, thereby preventing the central member 41 from being relatively cooled and preventing a temperature of the central member 41 from being lowered when the central member 41 received the wafer 1. By preventing the temperature of the central member 41 from being lowered when the central member 41 received the wafer 1, as shown in FIG. 15A, after the central member 41 was lowered, even if the central member 41 is heated uniformly with the first peripheral member 42 and the second peripheral member 43 by the heater 30, the temperature distribution of the wafer 1 is uniform and thus, the film thickness distribution and the film quality distribution of the CVD film formed on the wafer 1 become uniform.

The tweezer 2 which transferred the wafer 1 to the wafer lifting and lowering apparatus 50 in this manner goes out from the processing chamber 11 through the wafer carry in-out port 16. When the tweezer 2 went out from the processing chamber 11, the wafer carry in-out port 16 is closed by the gate valve 17.

As shown in FIG. 13, if the gate valve 17 is closed, the rotation drum 35 and the heating unit 27 are lifted by the rotation shaft 34 and the support shaft 26 with respect to the processing chamber 11. In the initial stage of the lifting operation of the rotation drum 35, the rotation-side pins 82 abut against the bottom surface of the processing chamber 11, i.e., the upper surface of the bottom cap 15, and the heater-side pins 85 is placed on the rotation-side ring 61. Therefore, the central member 41 supported by the push-up portions 87 of the rotation-side ring 81 is relatively gradually lowered with respect to the rotation drum 35 as the rotation drum 35 is lifted.

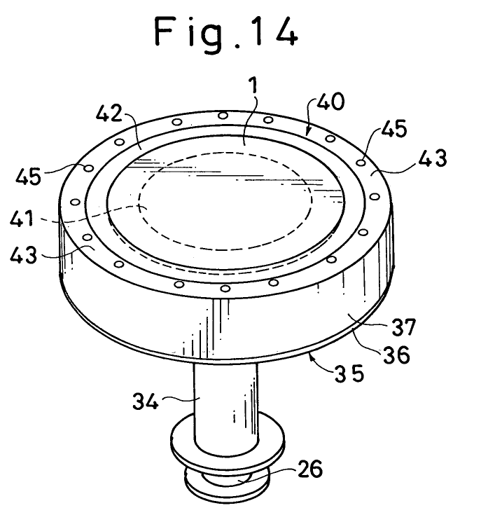

When the rotation-side pins 82 are separated from the bottom surface of the processing chamber 11, the push-up portions 87 are pulled below the susceptor 40. Therefore, as shown in FIG. 14, the central member 41 is fitted into the first peripheral member 42. In this state, the wafer 1 is completely moved on the susceptor 40, and the upper surface of the wafer 1, the upper surface of the first peripheral member 42 and the upper surface of the second peripheral member 43 are flush with each other.

The wafer 1 placed on the susceptor 40 is heated by the heater 30, and a temperature of the heater 30 and a temperature of the wafer 1 are measured by the thermocouples 33. A heating amount of the heater 30 is feedback controlled in accordance with the measured result of the thermocouples 33. Since the susceptor 40 is not formed with insertion holes through which the push-up portions 87 are inserted, the temperature distribution of the wafer 1 is uniform entirely irrespective of the existence of the wafer lifting and lowering apparatus 80. Further, as described above, when the susceptor 40 is received, since the central member 41 is previously heated, the temperature distribution of the wafer 1 is uniform entirely although the central member 41 received the wafer 1.

The rotation drum 35 and the heating unit 27 lifts the processing chamber 11 by the rotation shaft 34 and the support shaft 26, and stops lifting the processing chamber 11 at the height at which the upper surface of the wafer 1 approach the lower surface of the plate 22. The exhaust port 18 is evacuated by the vacuum exhaust apparatus.

Subsequently, the rotation drum 35 is rotated by the rotation shaft 34. At that time, the rotation-side pins 82 are separated from the bottom surface of the processing chamber 11, and the heater-side pins 85 are separated from the rotation-side ring 81. Therefore, the rotation of the rotation drum 35 is not hindered by the wafer lifting and lowering apparatus 80, and the stopped state of the heating unit 27 can be maintained. That is, in the wafer lifting and lowering apparatus 80, the rotation-side ring 81 rotates together with the rotation drum 35, and the heater-side ring 84 is stopped together with the heating unit 27.

When the exhaust amount of the exhaust port 18 and the rotation of the rotation drum 35 are stabilized, the processing gas 3 is introduced into the gas introducing ports 21. The processing gas 3 introduced into the gas introducing ports 21 flows into the gas reservoir 24 by the exhausting force of the exhaust port 18 acting on the gas reservoir 24, and disperse radially outward, and flows from the blowout ports 23 of the plate 22 substantially uniformly, and blows out like shower toward the wafer 1. The processing gas 3 blown out like shower from the blowout ports 23 is drawn into the exhaust port 18 and exhausted.

At that time, since the wafer 1 on the susceptor 40 supported by the rotation drum 35 is rotating, the processing gas 3 blown out like shower from the blowout ports 23 is brought into contact with the entire surface of the 1 uniformly. Further, since the upper surface of the wafer 1 and the upper surface of the outer side susceptor 40 are flush with each other, the flow of the processing gas 3 is prevented from being disturbed and is controlled uniformly. Because the processing gas 3 is in contact with the entire surface of the wafer 1 uniformly, the film thickness distribution and the film quality distribution of the CVD film formed on the wafer 1 by the processing gas 3 becomes uniform over the entire surface of the wafer 1.

Further, since the heating unit 27 is supported by the support shaft 26 and is not rotated, the temperature distribution of the wafer 1 which is heated by the heating unit 27 while being rotated by the rotation drum 35 is controlled uniformly in the circumferential direction. Since the susceptor 40 is not formed with the insertion holes through which the push-up portions 87 are inserted, and since the central member 41 is previously heated when receiving the susceptor 40, the temperature distribution of the wafer 1 is controlled uniformly over the entire wafer 1. If the temperature of the wafer 1 is uniformly over the entire surface, the film thickness distribution and the film quality distribution of the CVD film formed on the wafer 1 by the thermochemical reaction is controlled uniformly over the entire surface of the wafer 1.

When the CVD film is formed uniformly over the entire surface of the wafer 1 in the above-described manner and a predetermined processing time is elapsed, as shown in FIG. 11, the rotation drum 35 and the heating unit 27 are lowered to the transfer position by the rotation shaft 34 and the support shaft 26. At the halfway stage of the lowering movement, the rotation-side pin 82 of the wafer lifting and lowering apparatus 80 abut against the bottom surface of the processing chamber 11 and the heater-side pine 85 abut against the rotation-side ring 81. Therefore, by the above-described operation, the wafer lifting and lowering apparatus 80 floats up the wafer 1 by lifting the central member 41 of the susceptor 40.

Thereafter, by repeating the above-described operations, the CVD films are formed on the wafers 1 by the single wafer-fed CVD apparatus 10 one by one.

As explained above, in the third embodiment also, the wafer 1 can be transferred to and from by the mechanical wafer transfer apparatus. By rotating the susceptor 40 holding the wafer 1, the processing gas 3 can be brought into contact with the entire surface of the wafer 1 uniformly. Therefore, it is possible to control the film thickness distribution and the film quality distribution of the CVD film formed on the wafer 1 by the processing gas 3. The susceptor 40 holding the wafer 1 is rotated and the heating unit 27 is stopped, and therefore, it is possible to uniformly control, in the circumferential direction, the temperature distribution of the wafer 1 heated by, the heating unit 27 while the wafer 1 is rotated by the susceptor 40. Thus, the film thickness distribution and the film quality distribution of the CVD film formed on the wafer 1 by the thermochemical reaction can be controlled uniformly over the entire surface of the wafer 1.

Since the heating unit 27 is not rotated, the heater 30 and the thermocouples 33 can be disposed in the heating unit 27, and electric wires for the heater 30 and the thermocouples 33 can easily be provided in the heating unit 27.

Since the wafer lifting and lowering apparatus 80 for lifting and lowering the wafer 1 is disposed on the inner side of the susceptor 40, it is possible to prevent the wafer lifting and lowering apparatus 80 from projecting outside the rotation drum 35, and to prevent the volume of the processing chamber 11 from being increased.

Further, since the susceptor 40 is not formed with the insertion holes through which the push-up portions 87 are inserted, the temperature distribution of the wafer 1 can be controlled uniformly over the entire wafer 1 irrespective of the existence of the wafer lifting and lowering apparatus 80. When the susceptor 40 is received, since the central member 41 is previously heated, the temperature distribution of the wafer 1 can be controlled uniformly over the entire wafer 1 although the wafer 1 is received by the central member 41.

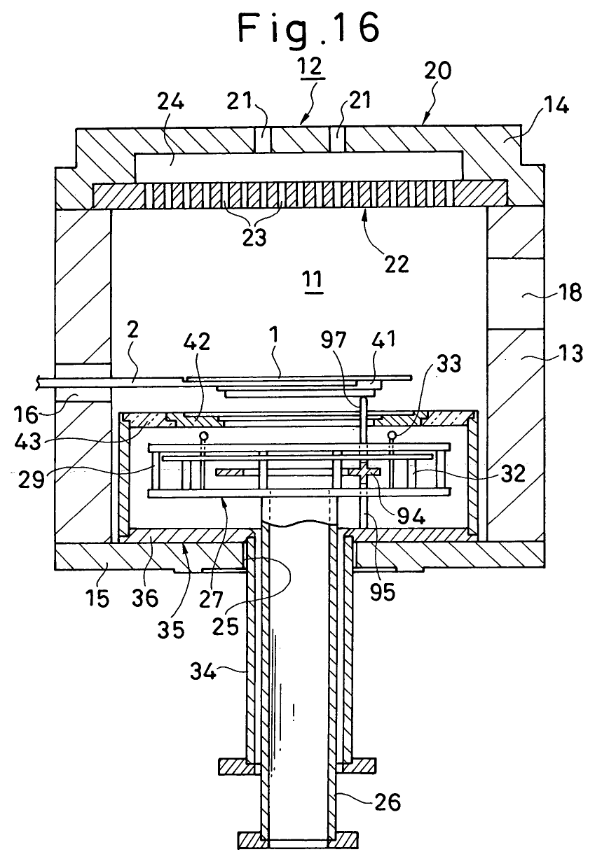

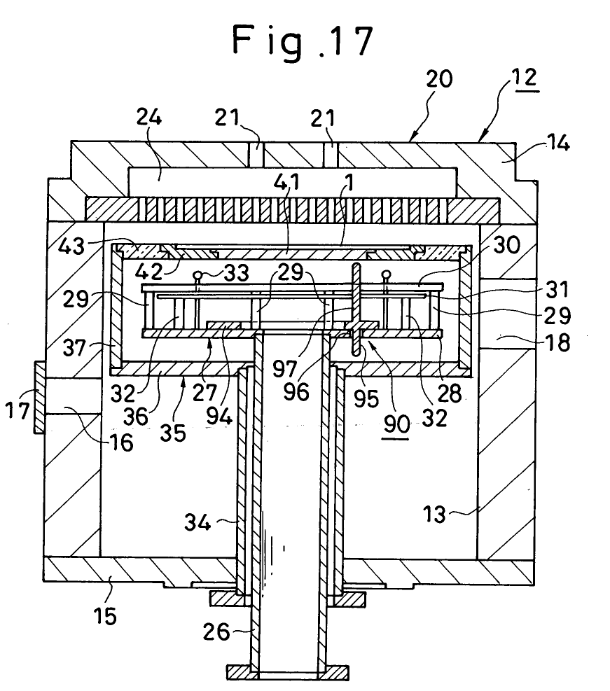

Next, a fourth embodiment of the present invention will be explained with reference to FIGS. 16 and 17.

The fourth embodiment is different from the third embodiment in that the rotation-side ring 81 is omitted in a wafer lifting and lowering apparatus 90, and the rotation drum 35 is lifted and lowered with respect to the heating unit 27.

That is, as shown in FIGS. 16 and 17, the support shaft 26 supporting the heating unit 27 is lifted and lowered with respect to the processing chamber 11, and the support shaft 26 to lifted and lowered independently with respect to the rotation shaft 34 supporting the rotation drum 35. A push-up pin 95 projects vertically downwardly from the lower surface of a lifting and lowering ring 94 of the wafer lifting and lowering apparatus 90. The push-up pin 95 is inserted through a guide hole 96 formed in the support plate 28 of the heating unit 27, and a lower end of the push-up pin 95 is opposed to the bottom surface of the rotation drum 35, i.e., the upper surface of the rotation plate 36 such that the lower end can abut against the bottom surface of the rotation drum 35, i.e., the upper surface of the rotation plate 36. A push-up portion 97 projects from an upper surface of the lifting and lowering ring 94. An upper end of the push-up portion 97 passes through the heater 30 and the susceptor 40 and is opposed to a lower surface of the central member 41 of the susceptor 40. That is, the push-up pin 95 and the push-up portion 97 do not interfere with the rotation drum 35 and the susceptor 40 when the rotation drum 35 rotates.

As shown in FIG. 16, when the wafer 1 is transferred in and out, the rotation drum 35 and the heating unit 27 are lowered to the transfer position of the processing chamber 11 by the rotation shaft 34 and the support shaft 26, and the rotation drum 35 is lowered by the rotation shaft 34 with respect to the heating unit 27. If the rotation drum 35 was lowered with respect to the heating unit 27, the lifting and lowering ring 94 of the wafer lifting and lowering apparatus 90 is lifted with respect to the rotation drum 35. If the heating and lowering ring 94 is lifted with respect to the rotation drum 35, the three push-up portions 97 standing on the lifting and lowering ring 94 support the central member 41 of the susceptor 40 from below, and float up the central member 41 from the first peripheral member 42 and the second peripheral member 43. Since the central portion of the wafer 1 is placed on the central member 41, the wafer 1 is floated up.

As shown in FIG. 16, when the wafer lifting and lowering apparatus 90 floats up the wafer 1 from the upper surface of the susceptor 40, the insertion space is formed below the wafer 1, i.e. between the lower surface of the wafer 1 and the upper surface of the susceptor 40. Therefore, a fork-like tweezer 2A of the wafer transfer apparatus is inserted into the insertion space of the wafer 1 from the wafer carry in-out port 16. That is, like the above-mentioned third embodiment, the wafer 1 can be transferred by the mechanical wafer transfer apparatus.

After the wafer 1 was transferred, as shown in FIG. 17, the rotation drum 35 and the heating unit 27 are lifted by the rotation shaft 34 and the support shaft 26 with respect to the processing chamber 11, and the rotation drum 35 is lifted by the rotation shaft 34 with respect to the heating unit 27. If the rotation drum 35 was lifted with respect to the heating unit 27, the central member 41 supported by the push-up portion 97 of the lifting and lowering ring 94 is lowered with respect to the rotation drum 35, and the central member 41 is fitted into the first peripheral member 42. In this state, the wafer 1 is moved onto the susceptor 40, and the upper surface of the wafer 1, the upper surface of the first peripheral member 42 and the upper surface of the second peripheral member 43 are flush with each other.

Thereafter, like the above-mentioned third embodiment, the wafer 1 is rotated by the rotation drum 35 and in this state, a film is formed on the wafer 1, and the entire wafer 1 is processed uniformly. At that time, the lifting and lowering ring 94 of the wafer lifting and lowering apparatus 90 is stopped together with the heating unit 27, the lower end of the push-up pin 95 is separated from the bottom surface of the rotation drum 35, and the upper end of the push-up portion 97 is separated from the lower surface of the susceptor 40 to permit the rotation of the rotation drum 35.

When the CVD film was formed uniformly over the entire surface of the wafer 1 in the above-described manner and a predetermined processing time is elapsed, as shown in FIG. 16 the rotation drum 35 and the heating unit 27 are lowered to the transfer position by the rotation shaft 34 and the support shaft 26, and the rotation drum 35 is lowered with respect to the heating unit 27. When the rotation drum 35 is lowered with respect to the heating unit 27, by the above-described operation, the wafer lifting and lowering apparatus 90 floats up the wafer 1 by lifting the central member 41 of the susceptor 40.

Thereafter, by repeating the above-described operations, the CVD films are formed on the wafers 1 by the single wafer-fed CVD apparatus 10 one by one.

As explained above, according to the fourth embodiment, in addition to the effect of the third embodiment, there is effect that the rotation-side ring 81, the rotation-side pins 82 and the guide hole 83 can be omitted, and the sliding portions can be reduced.

In the fourth embodiment, since the wafer lifting and lowering apparatus 90 lifting and lowering the wafer 1 by lifting and lowering the rotation drum 35 with respect to the heating unit 27. Therefore, as compared with the first to third embodiments, in which the wafer 1 is automatically lifted and lowered in association with the lifting and lowering motion of the rotation drum 35 and the heating unit 27 with respect to the processing chamber 11, the structure of the elevator for lifting and lowering the rotation shaft 34 and the support shaft 26 becomes slightly complicated.

The present invention is not limited to the above embodiments, and it is of course possible to make various modifications without departing from the gist of the present invention.

For example, the temperature sensor is not limited to the thermocouples, and another non-contact type temperature sensor may be used, or the temperature sensor may be omitted.

The substrate to be processed is not limited to the wafer, and the substrate to be processed may be a glass substrate for producing LCD (Liquid Crystal Display) apparatuses.

The present invention can be applied not only to the single wafer-fed cold wall type CVD apparatus, but also to a substrate processing apparatus such as a dry-etching apparatus.

As explained above, according to the present invention, the mechanical type substrate transfer apparatus can be used for transferring the substrate to be processed in and out. When the substrate to be processed is processed, the wafer is heated by the heating unit while rotating the substrate to be processed supported by the susceptor, thereby controlling the temperature distribution on the substrate to be processed uniformly over the entire wafer. Therefore, the substrate to be processed can be processed uniformly.

The entire disclosure of Japanese Patent Application No. 2000-84590 filed on Mar. 24, 2000 including specification, claims, drawings and abstract are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A substrate processing apparatus, comprising:
a processing chamber;
a susceptor on which a substrate to be processed is to be placed; and
a heating unit disposed below said susceptor for heating said substrate to be processed placed on said susceptor, wherein
said susceptor and said heating unit are accommodated in said processing chamber,
in a state in which said susceptor and said heating unit are relatively rotated, said substrate to be processed is processed,
at least said susceptor is lifted and lowered in said processing chamber, and
a substrate to be processed lifting and lowering apparatus for lifting and lowering said substrate to be processed with respect to at least a portion of said susceptor is disposed in said processing chamber.

2. A substrate processing apparatus as recited in claim 1, wherein
said heating unit is lifted and lowered in said processing chamber, and
said substrate to be processed lifting and lowering apparatus lifts or lowers said substrate to be processed with respect to at least the portion of said susceptor in association with lifting and lowering motion of said susceptor and said heating unit.

3. A substrate processing apparatus as recited in claim 1, wherein
when said substrate to be processed is lifted or lowered at least with respect to the portion of said susceptor, a distance between said susceptor and said heating unit is maintained constant.

4. A substrate processing apparatus as recited in claim 1, wherein said substrate to be processed lifting and lowering apparatus is disposed outside said susceptor.

5. A substrate processing apparatus as recited in claim 1, wherein said substrate to be processed lifting and lowering apparatus is disposed inside said susceptor.

6. A substrate processing apparatus as recited in claim 1, wherein
said susceptor comprises a central member and a peripheral member, and
said substrate to be processed lifting and lowering apparatus lifts and lowers said central member of said susceptor.

7. A substrate processing apparatus as recited in claim 6, wherein
a heater of said heating unit comprises a central heater member corresponding to the central member of said susceptor and a peripheral heater member corresponding to the peripheral member of said susceptor,
outputs of said central heater member and said peripheral heater member are independently controlled, and
the output of said central heater member is increased while the central member of said susceptor is lifted or lowered.

8. A substrate processing apparatus, comprising:
a susceptor disposed in a processing chamber and on which a substrate to be processed is to be placed, and
a heating unit disposed below said susceptor in said processing chamber for heating said substrate to be processed placed on said susceptor, wherein
an upper surface of a peripheral portion of said susceptor and an upper surface of said substrate to be processed placed on said susceptor are flush with each other.

9. A substrate processing apparatus as recited in claim 8, wherein
a member made of quartz which is flush with an upper surface of said susceptor is disposed in an outer periphery of said susceptor.

10. A substrate processing method using a substrate processing apparatus, comprising:
a processing chamber;
a susceptor on which a substrate to be processed is to be placed; and
a heating unit disposed below said susceptor for heating said substrate to be processed placed on said susceptor, wherein
said susceptor and said heating unit are accommodated in said processing chamber,
in a state in which said susceptor and said heating unit are relatively rotated, said substrate to be processed is processed,
at least said susceptor is lifted and lowered in said processing chamber, and
a substrate to be processed lifting and lowering apparatus for lifting and lowering said substrate to be processed with respect to at least a portion of said susceptor is disposed in said processing chamber, comprising the steps of:
transferring said substrate to be processed from said susceptor to said substrate to be processed lifting and lowering apparatus when said susceptor is lowered, and
processing said substrate to be processed when said susceptor is lifted in a state in which said substrate to be processed is placed by said susceptor.

11. A substrate processing apparatus as recited in claim 10, wherein
said susceptor comprises a central member and a peripheral member,
said substrate to be processed lifting and lowering apparatus lifts and lowers said central member of said susceptor,
when said susceptor is lowered, said substrate to be processed lifting and lowering apparatus lifts said central member to place said substrate to be processed onto said central member, and
then, the lifting operation of said central member is stopped and said substrate to be processed is transferred onto said susceptor including said peripheral member, and
when said susceptor is lifted, said substrate to be processed is processed in a state in which said substrate to be processed is placed by said susceptor.

12. A substrate processing apparatus as recited in claim 11, wherein
a heater of said heating unit comprises a central heater member corresponding to the central member of said susceptor and a peripheral heater member corresponding to a peripheral member of said susceptor,
outputs of said central heater member and said peripheral heater member are independently controlled,
the output of said central heater member is increased while the central member of said susceptor is lifted or lowered,
at the time of lowering operation of said susceptor, when said substrate to be processed lifting and lowering apparatus lifts said central member to place said substrate to be processed onto said central member, the output of said central member is increased, and
at the time of lifting operation of said susceptor, when said substrate to be processed is processed in a state in which said substrate to be processed is placed by said susceptor including said peripheral member, the output of said central heater member and the output of said peripheral heater member are controlled such that a temperature distribution of said substrate to be processed becomes uniform over the entire said substrate to be processed.
